(19) United States
(12) Patent Application Publication
(10) Pub. No.: US 2025/0185310 A1
(43) Pub. Date: Jun. 5, 2025

(54) METHOD FOR ELECTRICALLY CONTROLLING SPIN-POLARIZED SURFACE STATE, AND ELECTRICAL SWITCHING METHOD AND SWITCHING DEVICE USING SPIN-POLARIZED SURFACE STATE

(71) Applicant: POSTECH RESEARCH AND BUSINESS DEVELOPMENT FOUNDATION, Pohang-si (KR)

(72) Inventors: Byoung-don KONG, Pohang-si (KR); Jeongwook KIM, Pohang-si (KR); Suhyun PARK, Pohang-si (KR); Yunho LEE, Pohang-si (KR); Gyubin LEE, Pohang-si (KR); Dahyeon RYU, Pohang-si (KR)

(21) Appl. No.: 18/897,185

(22) Filed: Sep. 26, 2024

(30) Foreign Application Priority Data
Nov. 30, 2023 (KR) 10-2023-0171596

(51) Int. Cl. H01L 29/66

(52) U.S. Cl. CPC H10D 48/385

(57) ABSTRACT

An electrical switching method may include: preparing a semiconductor material layer comprising a first contact point and a second contact point, which are electrically separated from each other, and a semiconductor material connecting the first contact point and the second contact point and having a predetermined thickness; and, in order to control the electrical connection between the first contact point and the second contact point, causing phase transition of the semiconductor material to a topological insulator by applying an electric field having a direction perpendicular to the surface of the semiconductor material to the semiconductor material layer. The electric field has a magnitude determined by the maximum value of the valence band and the minimum value of the conduction band of the semiconductor material. Applying an electric field to shift the valence and conduction bands closer induces a spin-polarized surface state through spin-orbit coupling between both surface wave functions.

### CROSS-REFERENCE TO RELATED APPLICATION

This application claims priority to Korean Patent Application No. 10-2023-0171596, filed on Nov. 30, 2023, and all the benefits accruing therefrom under 35 U.S.C. § 119, the contents of which in its entirety are herein incorporated by reference.

### BACKGROUND

### 1. Field

Embodiments relate to a method for electrically controlling a spin-polarized surface state appearing in a semiconductor material, and an electrical switching method and a switching device using the spin-polarized surface state. More specifically, embodiments provide a condition and a method for electrically controlling a spin-polarized surface state of, e.g., a topological insulator, and a technology for applying the same.

### 2. Description of the Related Art

The semiconductor industry is evolving toward improving performance and power consumption by making components smaller and integrating them into limited areas. Recently, as the scale of semiconductor switching devices reaches the atomic level, previously undiscovered phenomena have appeared, and various researches such as new device structures or new channel materials have been attempted. In particular, over the past few years, there have been active attempts to utilize graphene or topological insulators in devices.

The spin-polarized surface state is the most important characteristic of topological insulators. In topological insulators, the spin-orbit coupling, which is a physical quantity proportional to the atomic number, acts as a bidirectional magnetic field applied to spin-up and spin-down electrons and induces a linear spin-polarized state at the edge of the material. The topological insulators include high-atomic-number structures such as mercury telluride (HgTe)/cadmium telluride (CdTe) quantum wells, bismuth antimonide (Bi_{1-X}Sb_{X}), bismuth telluride (Bi₂Te₃), bismuth selenide (Bi₂Se₃), antimony telluride (Sb₂Te₃), lead tin telluride (PbSnTe) and lead tin selenide (PbSnSe).

These materials have a band gap in their bulk but the edges are gapless due to spin polarization, and they are protected by time-reversal symmetry, making them robust to external perturbations. Additionally, these structures have high mobility because backscattering is prohibited by the selection rule. Therefore, attempts are being made to utilize the spin-polarized surface state in devices. For example, Korean Patent Registration Publication No. 10-1598542 discloses a logic device using a spin field-effect transistor including a channel of a magnetic material that selectively passes spin-polarized electrons on a gate electrode.

Since the gapless spin-polarized surface state that appears in the topological insulator is a physical property, the gapless spin-polarized surface state can be controlled to have a band gap only by breaking the symmetry of the material through magnetic perturbation, strain, or change of the structure itself. If the gapless spin-polarized surface state inherent in the topological insulator could be derived from semiconductor materials with a band gap, it could be utilized for implementation in next-generation semiconductor devices, but such a technology does not exist at present.

### SUMMARY

In an aspect, the present disclosure provides a method for electrically controlling a spin-polarized surface state, which enables implementation of a device having high mobility due to the characteristics of a gapless spin-polarized state when applied to a channel of a semiconductor device by providing a condition and a method capable of electrically controlling a spin-polarized surface state, and an electrical switching method and a switching device utilizing the spin-polarized surface state.

In an aspect, a method for electrically controlling a spin-polarized surface state comprises: causing phase transition to a topological insulator by applying, to a semiconductor material, an electric field having a direction perpendicular to the surface of the semiconductor material, wherein the electric field has a magnitude determined by a maximum value of a valence band and a minimum value of a conduction band of the semiconductor material.

According to an embodiment, said causing the phase transition comprises forming a spin-polarized surface state by inducing interaction between wave functions existing on both surfaces of the semiconductor material through spin-orbit coupling.

According to an embodiment, said causing the phase transition comprises applying an electric field such that a spin-polarized surface state electrically occurring in the semiconductor material is distributed linearly and a helical spin orientation is formed on the surface of the semiconductor material.

According to an embodiment, said causing the phase transition comprises determining the magnitude of the electric field so that a product of an intensity of the electric field applied to the semiconductor material and a thickness of the semiconductor material is greater than or equal to a band gap of the semiconductor material.

In an aspect, an electrical switching method comprises: preparing a semiconductor material layer comprising a first contact point and a second contact point, which are electrically separated from each other, and a semiconductor material connecting the first contact point and the second contact point and having a predetermined thickness; and in order to control the electrical connection between the first contact point and the second contact point, causing phase transition of the semiconductor material to a topological insulator by applying an electric field having a direction perpendicular to a surface of the semiconductor material to the semiconductor material layer, wherein the electric field has a magnitude determined by a maximum value of a valence band and a minimum value of a conduction band of the semiconductor material.

According to an embodiment, the semiconductor material layer is made of a direct bandgap semiconductor material having a spin-orbit coupling strength between graphene and a topological insulator and having symmetry between both surfaces.

According to an embodiment, the semiconductor material comprises silicon germanium (Si_{1-X}Ge_{X}) having a germanium (Ge) ratio of 85% or higher, the predetermined thickness is 3 nm or smaller, and said causing the phase transition comprises applying an electric field having a strength of 0.01×10¹² to 0.11×10¹² V/m to the semiconductor material layer.

According to an embodiment, the semiconductor material comprises a group III-V semiconductor material comprising gallium (Ga) or indium (In) but excluding gallium phosphide (GaP).

According to an embodiment, the semiconductor material comprises a group II-VI semiconductor material comprising cadmium (Cd) or zinc (Zn) but excluding cadmium oxide (CdO).

According to an embodiment, the semiconductor material comprises an alloy based on a group IV element.

According to an embodiment, said preparing the semiconductor material layer comprises stacking silicon germanium (Si₁₋ₓGe_{X}) having a germanium (Ge) ratio of 85% or higher in (111) direction.

In an aspect, a switching device comprises: a first conductive layer; a second conductive layer electrically separated from the first conductive layer; a channel layer connecting the first conductive layer and the second conductive layer, made of a semiconductor material and having a predetermined thickness; and a control unit configured to cause phase transition of the semiconductor material to a topological insulator by applying an electric field having a direction perpendicular to the surface of the semiconductor material to the channel layer to control electrical connection between the first contact point and the second contact point.

According to an embodiment, the channel layer is made of a direct bandgap semiconductor material having a spin-orbit coupling strength between graphene and a topological insulator and having symmetry between both end surfaces.

According to an embodiment, the control unit is further configured to selectively control the flow of current through the channel layer by applying an electric field to the channel layer so as to form a spin-polarized surface state by inducing interaction between wave functions existing on both surfaces of the semiconductor material through spin-orbit coupling.

According to an embodiment, the control unit is further configured to determine the magnitude of the electric field so that a product of an intensity of the electric field applied to the semiconductor material and a thickness of the semiconductor material is greater than or equal to the band gap of the semiconductor material.

According to an embodiment, the semiconductor material comprises silicon germanium (Si_{1-X}Ge_{X}) having a germanium (Ge) ratio of 85% or higher, and the predetermined thickness is 3 nm or smaller.

According to an embodiment, the semiconductor material is silicon germanium (Si₁₋ₓGe_{X}) stacked in (111) direction.

According to an embodiment, the channel layer comprises: a plurality of semiconductor material layers made of the semiconductor material; and a plurality of barrier layers, which are stacked alternately with the plurality of semiconductor material layers and are made of a material having a larger band gap than the semiconductor material layers.

According to an embodiment, the semiconductor material is silicon germanium (Si₁₋ₓGe_{X}) having a germanium (Ge) ratio of 85% or higher, and the barrier layer is made of silicon (Si).

In an aspect, a field-effect transistor comprises the switching device according to the above-mentioned embodiments.

According to the method for electrically controlling a spin-polarized surface state according to an aspect of the present disclosure and the electrical switching technology using the same, phase transition to a gapless topological insulator can be induced by applying an appropriate electric field to a conventional semiconductor material having a gap and, thereby, current flow through the semiconductor material can be controlled.

The method for electrically controlling a spin-polarized surface state according to an aspect of the present disclosure and the electrical switching technology using the same are new technologies for inducing spin-orbit coupling by interaction between surface wave functions at both ends of a material placed under an external electric field. If these technologies are applied to switching devices such as a field-effect transistor, etc., it is possible to produce devices with high mobility without doping, which is advantageous in implementing high-performance, high-integration devices.

### BRIEF DESCRIPTION OF THE DRAWINGS

FIGS. 1A and 1B are conceptual diagrams for explaining the interaction between wave functions depending on the distance between the two surfaces of a material.

FIG. 2 is a flowchart showing each step of an electrical switching method according to an exemplary embodiment.

FIG. 3 is a conceptual diagram describing conversion of silicon germanium (Si_{1-X}Ge_{X}), which is an indirect bandgap material, into a direct bandgap material.

FIGS. 4A and 4B show a result of calculating the band structure of Si_{0.05}Ge_{0.95} bulk and the band structure of 1.6 nm-thick Si_{0.05}Ge_{0.95} (111) nanosheet, respectively, by virtual crystal approximation (VCA).

FIGS. 5 to 8 show band structures in which the interaction between a valence band and a conduction band is induced using an electric field according to exemplary embodiments.

FIG. 9 shows a band structure in which a spin-orbit coupling band gap is created due to an electric field according to an exemplary embodiment.

FIG. 10 is a conceptual diagram showing a local density of state corresponding to the band structure of FIG. 7.

FIGS. 11A and 11B show the x-axis and y-axis components of spin components corresponding to the upper and lower Dirac cones of the band structure shown in FIG. 7, respectively.

FIG. 12 shows the intensity of an electric field forming a linear spin-polarized surface state depending on the thickness of a semiconductor material according to an exemplary embodiment.

FIG. 13A is a conceptual diagram of a supercell structure in which the numbers of silicon atoms on both surfaces of a semiconductor material are different.

FIG. 13B is a conceptual diagram of a supercell structure in which the numbers of silicon atoms on both surfaces of a semiconductor material are the same.

FIG. 13C is a conceptual diagram of a supercell structure in which both surfaces of a semiconductor material are composed only of germanium (Ge).

FIG. 14 shows the band structure of the supercell structures shown in FIGS. 13A to 13C.

FIG. 15 is a cross-sectional view of a field-effect transistor using silicon germanium (Si_{1-X}Ge_{X}) as a channel, as a switching device according to an exemplary embodiment.

FIG. 16 is a cross-sectional view of a field-effect transistor using silicon germanium (Si_{1-X}Ge_{X}) stacked alternately with silicon (Si) layers as a channel, as a switching device according to another exemplary embodiment.

### DETAILED DESCRIPTION

Hereinafter, exemplary embodiments of the present disclosure will be described in detail with reference to attached drawings.

In describing the exemplary embodiments of the present specification, if it is determined that a specific description of a known configuration or function may obscure the gist of the exemplary embodiments, a detailed description thereof will be omitted. In the drawings, the parts that are not related to the description of the exemplary embodiments of the present specification are omitted, and similar parts are given similar reference numerals.

In the exemplary embodiments of the present specification, when a component is said to be “connected,” “coupled,” or “joined” to another component, this may include not only a direct connection relationship, but also an indirect connection relationship in which another component exists therebetween. Additionally, when a component is said to “include” or “have” another component, this does not exclude the presence of another component but rather implies that further components may be included, unless specifically stated otherwise.

In the exemplary embodiments of this specification, the terms first, second, etc. are used only for the purpose of distinguishing one component from another component, and do not limit the order or importance between the components unless specifically stated. Accordingly, within the scope of the exemplary embodiments of the present specification, a first component in an exemplary embodiment may be referred to as a second component in another exemplary embodiment, and similarly, a second component in an exemplary embodiment may be referred to as a first component in another exemplary embodiment.

Unless defined otherwise, all terms used herein, including technical or scientific terms, have the same meaning as commonly understood by one of ordinary skill in the art to which the present disclosure belongs. Terms defined in commonly used dictionaries should be interpreted as having meanings consistent with their meanings in the context of the relevant art, and are not be interpreted in an idealized or overly formal sense, unless expressly defined otherwise in this specification.

When a layer is described to be “on” another layer or a substrate in the present specification, it may be formed directly on the another layer or the substrate, or there may be a third layer interposed therebetween. In addition, directional expressions such as top, upper (part), upper surface, etc. in this specification can be understood to mean bottom, lower (part), lower surface, etc. depending on the standard. That is, the expression of spatial direction should be understood as a relative direction and should not be interpreted as meaning an absolute direction.

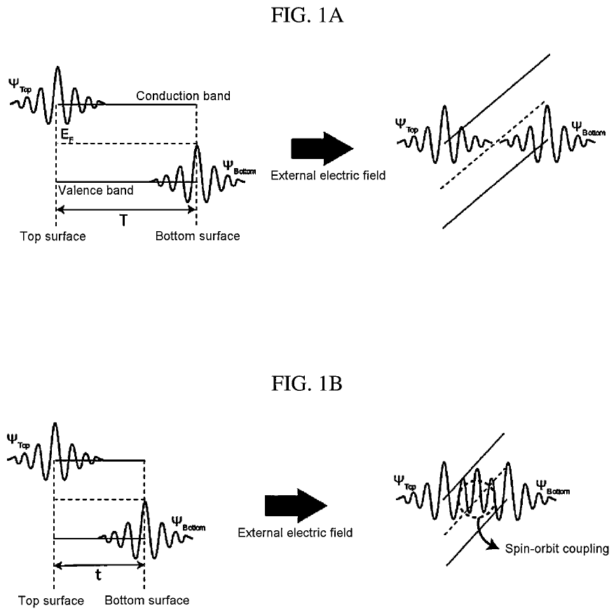

FIGS. 1A and 1B are diagrams for explaining the principle of a method for electrically controlling a spin-polarized surface state according to exemplary embodiments of the present disclosure, showing wave functions of a lower surface of a semiconductor material located in a valence band (ψ_{Bottom}) and wave functions of an upper surface of the semiconductor material located in a conduction band (ψ_{Top}).

As shown in FIG. 1A, if the thickness (T) of the semiconductor material is relatively large (i.e., if the distance between the two surfaces of the semiconductor material is large), even when the wave function (ψ_{Bottom}) of the bottom surface of the semiconductor material is shifted to the conduction band due to an external electric field, no interaction occurs between the wave functions. On the other hand, if the thickness (t) of the semiconductor material is smaller than a certain level as illustrated in FIG. 1B (i.e., if the distance between the two surfaces of the semiconductor material is small), when an appropriate external electric field is applied, the wave function of the bottom surface of the semiconductor material (ψ_{Bottom}) is shifted to the conduction band, and spin-orbit coupling occurs between the wave function of the top surface of the semiconductor material (ψ_{Top}) and the wave function of the bottom surface (ψ_{Bottom}).

The exemplary embodiments of the present disclosure are directed to achieving electrical switching by utilizing the phenomenon in which a linear spin-polarized surface state is induced at the edge of a semiconductor material having a gap that is not normally a topological insulator, as spin-orbit coupling acts as a bidirectional magnetic field applied to spin-up and spin-down electrons.

To this end, a method for electrically controlling a spin-polarized surface state according to an exemplary embodiment of the present disclosure includes a step of causing phase transition to a topological insulator by applying, to a semiconductor material, an electric field having a direction perpendicular to the surface of the semiconductor material. The magnitude of the electric field is determined by the maximum value of the valence band and the minimum value of the conduction band of the semiconductor material. For example, the electric field can be applied to have a magnitude greater than the gap between the maximum value of the valence band and the minimum value of the conduction band, so that the wave function (ψ_{Bottom}) at the bottom surface of the semiconductor material can be determined to have a magnitude that can be shifted to the conduction band by the electric field.

As described above, since the semiconductor material in which the phase transition occurs has a spin-polarized state induced at the edge, it is robust to external perturbation and has high mobility due to suppressed backscattering. Electrical switching becomes possible since a relatively large amount of current is allowed to flow when the spin-polarized state is induced (i.e., when an electric field is applied), and a relatively small amount of current is allowed to flow when the spin-polarized state is not induced (i.e., when no electric field is applied).

The semiconductor material may be configured to have a relatively thin thickness (e.g., 3 nm or smaller) so that the intensity of the electric field, which is calculated by dividing the applied voltage by the thickness of the semiconductor material, becomes larger than the gap between the maximum value of the valence band and the minimum value of the conduction band. For example, the semiconductor material may be in the form of a nanosheet, although not being limited thereto.

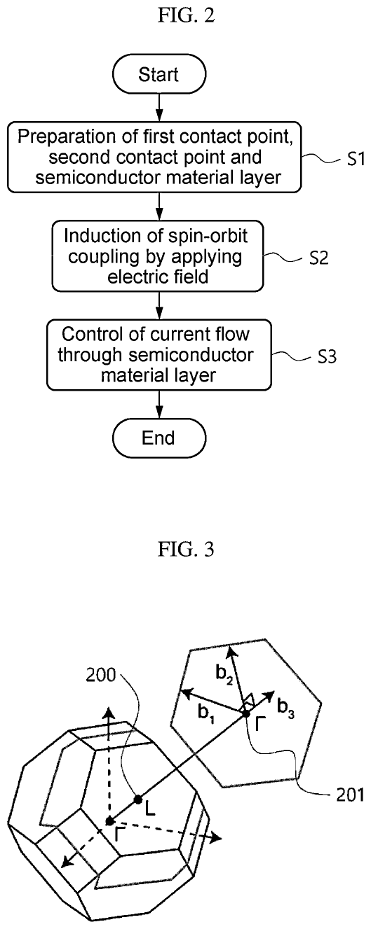

FIG. 2 is a flowchart showing each step of an electrical switching method through electrical control of a spin-polarized surface state according to an exemplary embodiment.

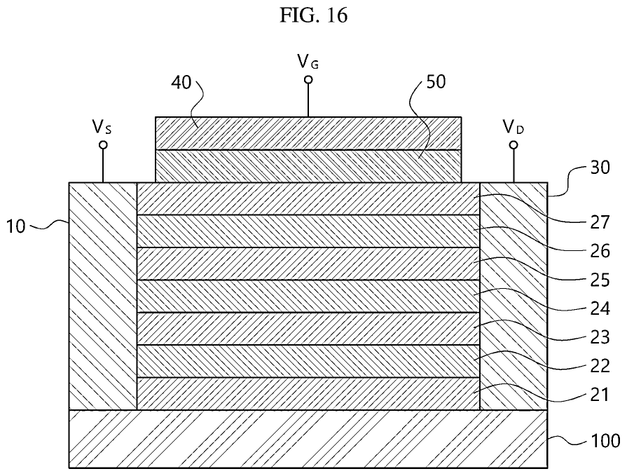

Referring to FIG. 2, according to an exemplary embodiment, electrical switching can be achieved (S2) by inducing spin-orbit coupling between the wave functions existing on both surfaces of the semiconductor material layer by applying an electric field to a device including a semiconductor material layer disposed between two electrically separated contact points (S1). For example, the contact points positioned with the semiconductor material layer interposed therebetween may refer to a contact point between the channel and the source electrode (also referred to as a first contact point) and a contact point between the channel and the drain electrode (also referred to as a second contact point) in a transistor device. This structure will be described in detail later with reference to FIGS. 15 and 16.

When spin-orbit coupling between wave functions existing at both ends of the semiconductor material layer is induced by applying an appropriate electric field, a phase transition of the semiconductor material layer to a topological insulator, i.e., a gapless spin-polarized surface state at the edge of the semiconductor material layer, is induced, thereby changing the current flow through the semiconductor material layer (S3). At this time, the electric field should be an electric field having a direction perpendicular to the surface of the semiconductor material. Since the spin-polarized surface state can be turned on/off through application of an electric field, it can be used to implement a new switching device.

In order to realize the method for electrically controlling a spin-polarized surface state according to exemplary embodiments, the semiconductor material to which an electric field is applied should i) be a material that is not a universal topological insulator (i.e., a material that is a topological insulator even when no electric field is applied), but be able to induce a spin polarization phenomenon by increasing the spin coupling strength by the electric field, ii) be a direct bandgap semiconductor material, iii) have a distance between the two end surfaces smaller than a predetermined value, and iv) have symmetry between the two end surfaces of the semiconductor material.

In this specification, the presence of symmetry between the two end surfaces is not limited to a state in which the two end surfaces of the semiconductor material are ideally perfectly symmetrical, but refers to a state in which the degree of symmetry of the arrangement of atoms constituting the material (e.g., hydrogen (H), silicon (Si) and germanium (Ge)) at the two end surfaces is higher than a predetermined level to the extent that a spin-polarized surface state can occur.

With respect to the above condition i), in general, the spin coupling strength increases as the atomic number increases. For example, bismuth selenide exhibits strong spin-orbit coupling strength, and corresponds to a universal topological insulator. On the other hand, materials in the middle of the periodic table with relatively small atomic numbers or materials with properties resulting from the arrangement of crystal structures, such as phosphorene, can induce spin polarization when an electric field is applied perpendicularly to the surface. Therefore, in an exemplary embodiment, the semiconductor material may be composed of a material in the middle of the periodic table, such as germanium (Ge), and materials with higher atomic numbers.

With respect to the above condition ii), the electric field applied to the semiconductor material to induce the spin-polarized surface state is determined to have a magnitude determined by the maximum value of the valence band and the minimum value of the conduction band of the semiconductor material. In order for the maximum value of the valence band and the minimum value of the conduction band to be close to each other by applying an electric field of such a magnitude, so that the wave function at the bottom surface of the semiconductor material can be shifted to the conduction band by the electric field, the semiconductor material should be a direct bandgap material in which the momentum (k) in the valence band and the conduction band is the same. It is because, since the semiconductor material according to the exemplary embodiment is a material whose spin-orbit coupling is not as strong as that of a topological insulator, spin-orbit coupling can occur only when the maximum value of the valence band and the minimum value of the conduction band are close to each other.

With respect to the above condition iii), since spin-orbit coupling between the wave functions does not occur when the distance between the two end surfaces of the semiconductor material is greater than a certain level as described above with reference to FIGS. 1A and 1i, the thickness of the semiconductor material layer may be set to a determined thickness (e.g., 3 nm or smaller) at which spin-orbit coupling between the wave functions of the two end surfaces of the semiconductor material can occur. The spin-polarized surface state that appears at this time may be a linear distribution.

In an exemplary embodiment, the semiconductor material satisfying the above-described spin-polarized surface state formation conditions i) to iv) may be silicon germanium (Si_{1-X}Ge_{X}).

In another exemplary embodiment, the semiconductor material satisfying the spin-polarized surface state formation conditions i) to iv) may be a III-V semiconductor material formed from a group III element and a group V element, and may include gallium (Ga) and/or indium (In). For example, a group III-V semiconductor material such as GaAs (gallium arsenide) and InAs (indium arsenide) can be used, but GaP (gallium phosphide) is excluded.

In another exemplary embodiment, the semiconductor material satisfying the spin-polarized surface state formation conditions i) to iv) may be a II-VI semiconductor material formed from a group II element and a group VI element, and may include cadmium (Cd) and/or zinc (Zn). For example, a group II-VI semiconductor material such as CdS (cadmium sulfide) or ZnSe (zinc selenide) can be used, but cadmium oxide (CdO) is excluded.

In another exemplary embodiment, the semiconductor material satisfying the spin-polarized surface state formation conditions i) to iv) may include an alloy based on a group IV element such as tin germanium (SnGe).

In the following specification, a method for electrically controlling a spin-polarized surface state and electrical switching device and method according to exemplary embodiments are described, using silicon germanium (Si_{1-X}Ge_{X}) as an example of the semiconductor material satisfying the above-mentioned spin-polarized surface state formation conditions i) to iv). However, the exemplary embodiments of the present disclosure may also be implemented using other semiconductor materials that satisfy the above-described spin-polarized surface state formation conditions, and the semiconductor material used in the exemplary embodiments is not limited to silicon germanium (Si_{1-X}Ge_{X}).

In an exemplary embodiment, the step (Si) of preparing the semiconductor material layer may include a step of stacking silicon germanium (Si₁₋ₓGeₓ) in (111) direction. This is to convert silicon germanium (Si_{1-X}Ge_{X}), which is an indirect bandgap material, into a direct bandgap material. At this time, the ratio of germanium (Ge) in the silicon germanium (Si_{1-X}Ge_{X}) may be 85% or higher.

FIG. 3 is a conceptual diagram describing conversion of silicon germanium (Si_{1-X}Ge_{X}), which is an indirect bandgap material, into a direct bandgap material. Silicon germanium (Si_{1-X}Ge_{X}) is a semiconductor material whose conduction band minimum is located at L point (200) when the ratio of germanium (Ge) is 85% or higher. When the ratio of germanium (Ge) satisfies the above condition, the spin-polarized surface state formation condition i) can be satisfied due to the high ratio of germanium (Ge).

In addition, when the silicon germanium (Si_{1-X}Ge_{X}) is stacked in the (111) direction, since the minimum value of the conduction band is projected from the L point (200) to the F point (201), silicon germanium (Si_{1-X}Ge_{X}) becomes a material having a direct bandgap at the Γ point (201), and thus can satisfy the spin-polarized surface state formation condition ii) described above.

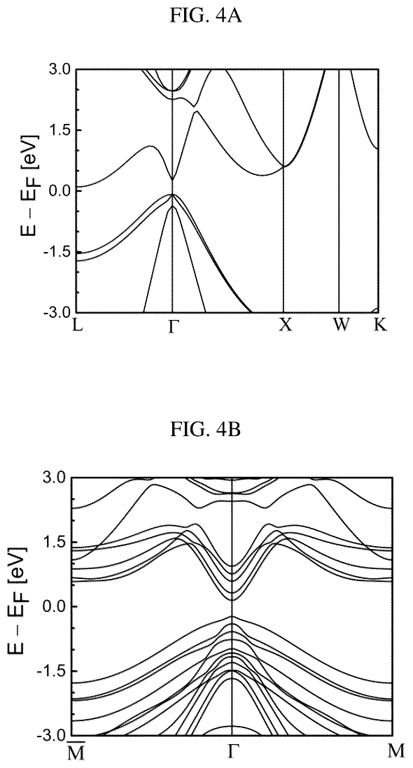

FIGS. 4A and 4B show a result of calculating the band structure of Si_{0.05}Ge_{0.95} bulk and the band structure of 1.6 nm-thick Si_{0.05}Ge_{0.95} (111) nanosheet, respectively, according to exemplary embodiments by virtual crystal approximation (VCA).

As shown in the figures, when silicon germanium (Si_{0.05}Ge_{0.95}), which is an indirect bandgap material, is stacked in the (111) direction, it is projected as a material having a direct bandgap at the F point, and the (111) nanosheet has a band gap of 0.378 eV. Degeneracy into a heavy hole band and a light hole band in the valence band and a split-off band due to the spin-orbit coupling can be confirmed. If the strength of spin-orbit coupling is too small, the split-off bands have small splitting energy between the heavy hole band and the light hole band and, if the strength of spin-orbit coupling is too strong, band inversion occurs and the material itself becomes a topological insulator having a spin-polarized surface state. Therefore, it can be seen from FIG. 4B that the Si_{0.05}Ge_{0.95} (111) nanosheet with a thickness of 1.6 nm satisfies the conditions for forming a spin-polarized surface state according to exemplary embodiments.

Meanwhile, the thickness of the semiconductor material layer capable of inducing a spin-polarized surface state may vary depending on the type of semiconductor material. In addition, the symmetry of the surfaces at both ends of the semiconductor material in the spin-polarized surface state formation condition iv), even if the silicon germanium (Si_{1-X}Ge_{X}) has an alloy structure in which silicon and germanium are distributed randomly, is satisfied automatically since virtual crystal approximation is used.

In order to achieve symmetry, in an exemplary embodiment, the semiconductor material layer may be prepared by a method of growing a silicon germanium (Si_{1-X}Ge_{X}) layer while changing the ratio of X, for example, by molecular beam epitaxy (MBE), or it may be deposited to ensure symmetry by covering both surfaces of the silicon germanium (Si_{1-X}Ge_{X}) layer only with germanium (Ge). However, the type of the semiconductor material layer and the method of preserving its symmetry can be achieved by other methods without being limited to the above-described exemplary embodiments. In the case of an alloy, symmetry is preserved through subsequent supercell calculation as will be described later.

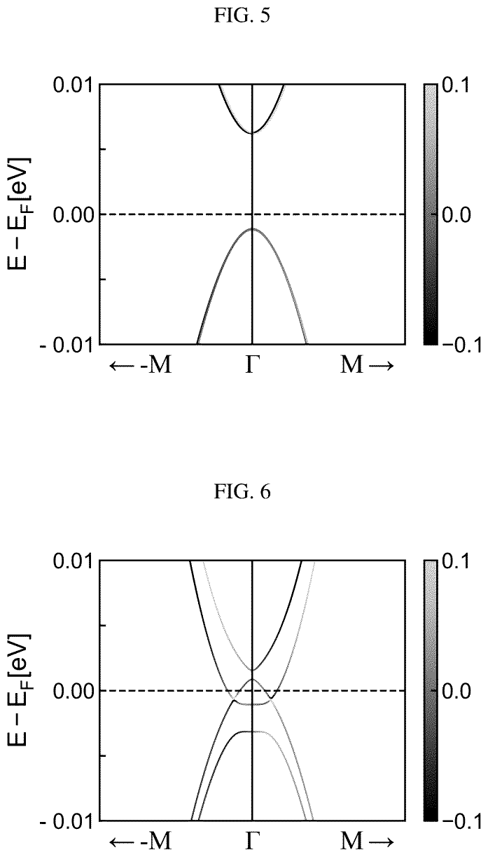

FIG. 5 shows a band structure in which a first interaction between the valence band and the conduction band occurs due to an electric field in a method for electrically controlling a spin-polarized surface state according to an exemplary embodiment. The band structure is one achieved when an electric field with an intensity of 103.0 mV/A is applied. The first interaction may occur as the conduction band and valence band become closer due to the external electric field perpendicular to the surface. It can be seen that the splitting of degenerate bands occurs within the valence band and conduction band.

FIG. 6 shows a band structure in which a second interaction occurs between the valence band and the conduction band due to an electric field in a method for electrically controlling a spin-polarized surface state according to an exemplary embodiment. The band structure is one achieved when an electric field with an intensity of 105.7 mV/Å is applied. It can be seen that band inversion occurs between the splitting bands with a stronger electric field, and spin-orbit coupling induces spin-flip at the anti-crossing point.

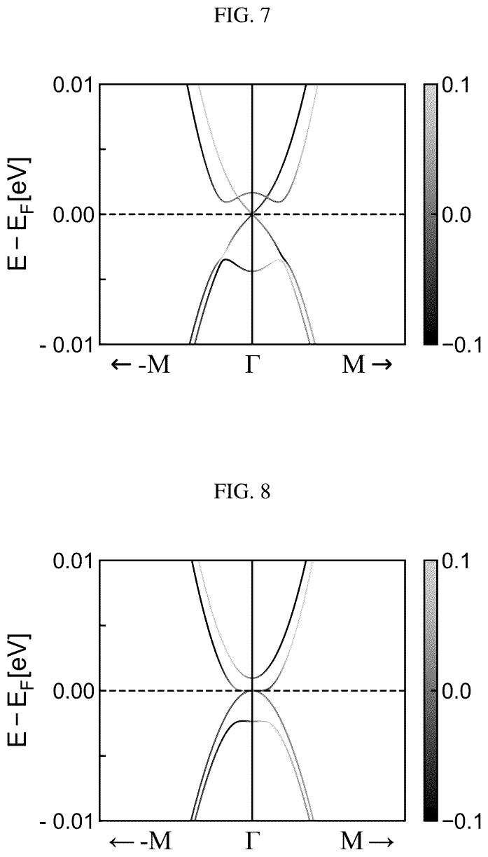

FIG. 7 shows a band structure in which a third interaction occurs between the valence band and the conduction band due to an electric field in a method for electrically controlling a spin-polarized surface state according to an exemplary embodiment. The band structure is one achieved when an electric field with an intensity of 106.1 mV/Å is applied. Referring to FIGS. 6 and 7, it can be seen that the anti-crossing prevents bending of the valence band and conduction band due to the electric field, and the anti-crossing between the valence bands induces spin flip, forming a single linear spin-polarized surface state that meets at the Fermi level.

In order to induce a spin-polarized surface state with the method for electrically controlling a spin-polarized surface state according to an exemplary embodiment, the product of the strength of the external electric field applied to the semiconductor material and the thickness of the semiconductor material (e.g., a nanosheet) should be equal to the band gap. In this case, the maximum value of the valence band coincides with the minimum value of the conduction band and, as a result, interaction can occur between the wave functions.

Meanwhile, when considering the change in dielectric constant depending on the thickness of the semiconductor material, the change in charge distribution depending on the application of an electric field, etc., the intensity of the external electric field applied to the semiconductor material may be determined so that the product of the intensity of the external electric field and the thickness of the semiconductor material is greater than the band gap while being proportional to the band gap of the semiconductor material.

At this time, the strength of the electric field that induces the spin-polarized surface state is determined in proportion to the band gap of the semiconductor material. This is distinct from the conventional topological insulator BHZ model, in which band inversion leads to linear spin polarization at the edges of the material, in that the effect of spin-orbit coupling is induced by an external electric field perpendicular to the surface of the semiconductor material, thereby splitting the degenerate bands, such that one pair of bands undergo band inversion and the other pair of bands induce a spin-polarized state.

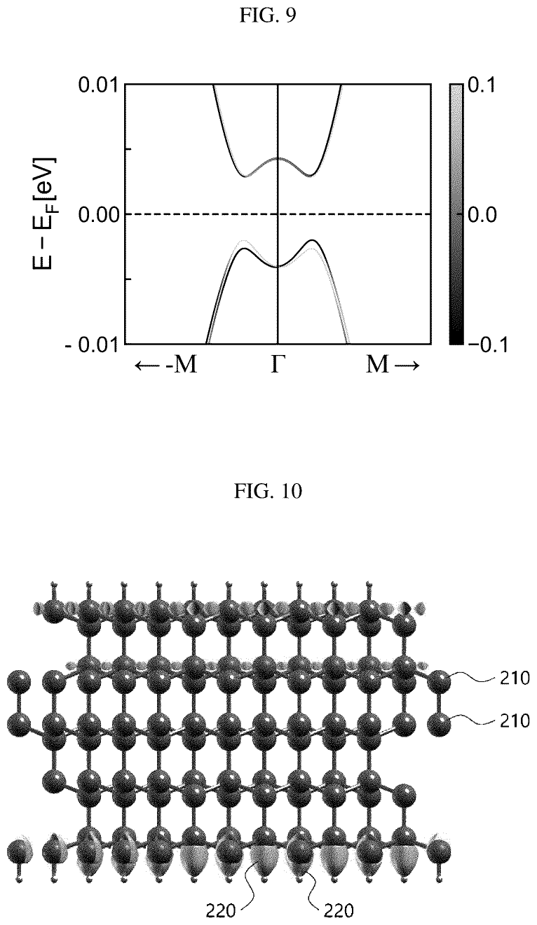

FIG. 8 shows a band structure in which a fourth interaction occurs between the valence band and the conduction band due to an electric field in a method for electrically controlling a spin-polarized surface state according to an exemplary embodiment. The band structure is one achieved when an electric field with an intensity of 108.1 mV/Å is applied. It can be seen that the linear spin-polarized surface state disappears due to the stronger electric field, leading to narrowing of the divided conduction band and valence band.

FIG. 9 shows a band structure in which a spin-orbit coupling band gap is created due to an electric field in a method for electrically controlling a spin-polarized surface state according to an exemplary embodiment. The band structure is one achieved when an electric field with an intensity of 111.5 mV/Å is applied. As the strength of the electric field increases, the divided conduction and valence bands degenerate again eventually, and a spin-orbit coupling band gap is formed between the conduction and valence bands.

However, the result shown in FIG. 9 is different from the band inversion between the divided bands shown in FIG. 8. In the band structure shown in FIG. 8, the Z2 topological number can be changed to 1 by the change in the product of the parity eigenvalues because band inversion occurs only between the bands divided at the time-invariant point. But, in the band structure shown in FIG. 9, where an electric field is applied, band inversion occurs in all of the degenerate bands, so the product of the parity eigenvalues does not change, implying that no phase transition occurs.

As described above with reference to FIGS. 5 to 9, a single linear spin-polarized surface state can be formed by inducing spin-orbit coupling via interaction between the conduction band and the valence band. It can be confirmed from the following drawings that phase transition has occurred from a general insulator to a topological insulator.

FIG. 10 is a conceptual diagram showing a local density of state corresponding to the band structure of FIG. 7. It shows that a linear spin-polarized surface state, which is a result of the interaction of electrically generated wave functions in the local density of state (220) having an equivalent surface of Si_{0.05}Ge_{0.95} (210) and 0.00004 states/eV, is formed on the surface of the nanosheet. It is identical to the characteristic of the linear spin-polarized surface state that appears in topological insulators.

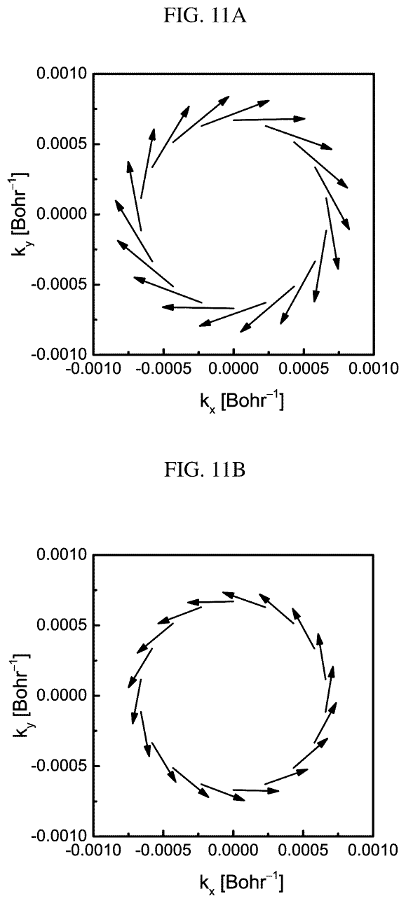

FIGS. 11A and 11B are graphs showing the spin orientations at the top and bottom of the Fermi level of the linear spin-polarized surface state shown in FIG. 7, respectively. In addition, as shown in FIGS. 11A and 11B, the electrically induced linear spin-polarized surface state has a helical spin orientation on the surface (x- and y-axis components) of the semiconductor material. Meanwhile, since the z-axis component of the spin-polarized surface state is polarized in the same spin orientation, it can be seen that the semiconductor material in which the linear spin-polarized surface state is induced according to the exemplary embodiments can be utilized for a spin-utilizing device.

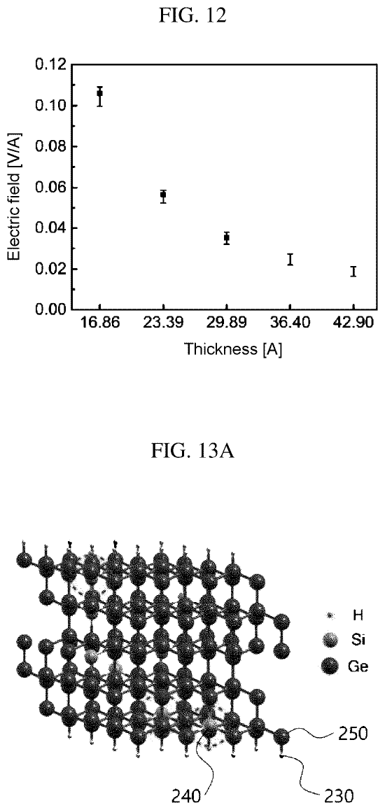

FIG. 12 shows the electric field in which a linear spin-polarized surface state is formed depending on the thickness of a Si_{0.05}Ge_{0.95} (111) nanosheet according to an exemplary embodiment. The black bars shown in FIG. 12 represent the electric field region where interaction between the conduction band and the valence band occurs, and the black dots represent the strength of the electric field at which a linear spin-polarized surface state is formed. From the figure, it can be seen that the critical thickness of the nanosheet where the interaction between the conduction band and the valence band occurs is 3 nm.

Considering the result shown in FIG. 12, it can be seen that the thickness of the semiconductor material layer may be 3 nm or smaller in an exemplary embodiment. Additionally, in an exemplary embodiment, the strength of the electric field applied to the semiconductor material layer may be 0.01×10¹² to 0.11×10¹² V/m. However, the critical thickness of the semiconductor material layer and the required intensity of the electric field may vary depending on the material, and therefore are not limited to the values mentioned above.

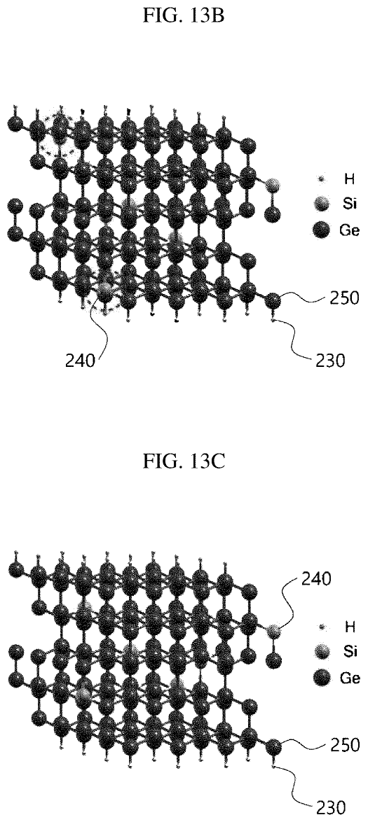

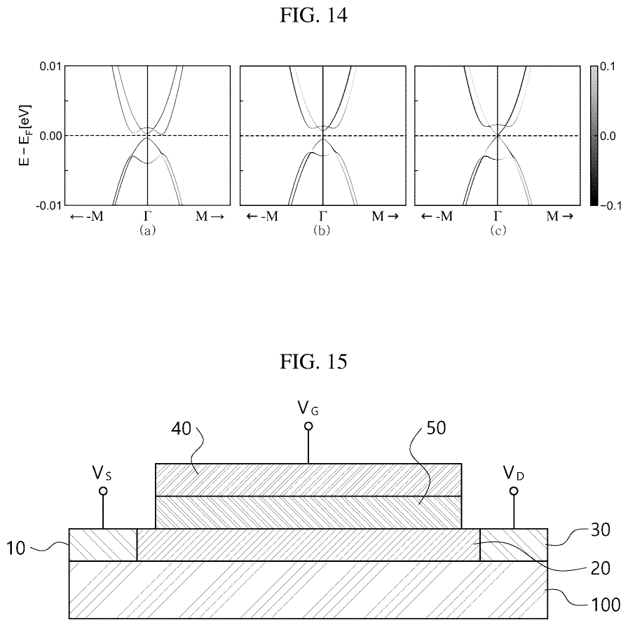

FIGS. 13A to 13C are conceptual diagrams showing the supercell structures of silicon germanium (Si_{1-X}Ge_{X}) as a semiconductor material according to exemplary embodiments, and FIG. 14 shows the band structure of the supercell structures shown in FIGS. 13A to 13C.

As shown in FIG. 13C, it can be seen that a linear spin-polarized surface state occurs when the arrangement of hydrogen (230), silicon (240) and germanium (250) is symmetrical at both ends of the material (i.e., satisfies the spin-polarized surface state formation condition iv) according to exemplary embodiments). However, unlike silicon germanium (Si_{1-X}Ge_{X}), which is an alloy structure in which the atoms are arranged randomly, this symmetry does not need to be considered in the case of semiconductor materials that satisfy other spin-polarized surface state formation conditions.

A semiconductor material in which a spin-polarized surface state can be induced by applying an electric field perpendicularly to the surface, such as silicon germanium (Si_{1-X}Ge_{X}), can be utilized as a channel material for a switching device such as a field-effect transistor (FET).

When a semiconductor material such as silicon germanium (Si_{1-X}Ge_{X}), etc. exists in vacuum, the energy band of the vacuum acts as a wide bandgap material, and a spin-polarized surface state can be formed even when the semiconductor material exists between other wide bandgap materials. The wide bandgap material is not limited to vacuum and may include an insulating film, a type 1 quantum well, a type 2 quantum wells, etc. When a type 2 quantum well is formed, a type 1 quantum well can also be formed by an external stimulus (e.g., strain).

FIG. 15 is a cross-sectional view of an FET using silicon germanium (Si_{1-X}Ge_{X}) as a channel, as a switching device according to an exemplary embodiment.

Referring to FIG. 15, a switching device according to an exemplary embodiment includes a first conductive layer (10), a second conductive layer (30) electrically separated from the first conductive layer (10), a channel layer (20) connecting the first conductive layer (10) and the second conductive layer (30) and formed of a semiconductor material, and a control unit configured to convert the semiconductor material of the channel layer 20 to a topological insulator by applying an electric field having a direction perpendicular to a surface of the channel layer (20).

In the case of a FET, the first conductive layer (10) may be a source electrode, the second conductive layer (30) may be a drain electrode, and the control unit may be electrically connected to a gate electrode (40) to control the electric field applied to the channel layer (20). Additionally, the gate electrode (40) may be positioned on the channel layer (20) with a gate insulating film (50) therebetween. Furthermore, each of the aforementioned components of the FET can be formed on a substrate (100).

When the control unit applies an input signal of an appropriate size through a gate terminal (V_{G}), an electric field that forms a linear spin-polarized surface state in the semiconductor material of the channel layer (20) is applied by the gate electrode (40), so that the channel layer (20) is converted to a topological insulator. In this case, backscattering in the channel layer (20) is suppressed, so that electrons with high mobility can move from the source electrode (10) toward the drain electrode (30).

In an exemplary embodiment, the channel layer of the switching device is not limited to being composed of a single layer of the semiconductor material, but may be composed of a multilayer structure in which semiconductor material layers (22, 24, 26) and barrier layers (21, 23, 25, 27) having a larger band gap than the semiconductor material layers (22, 24, 26) are arranged sequentially and alternately, as illustrated in FIG. 16.

The semiconductor material layers (22, 24, 26) may be formed of a semiconductor material that satisfies the conditions for forming a spin-polarized surface state, such as silicon germanium (Si_{1-X}Ge_{X}) according to exemplary embodiments described above. And, the barrier layer (21, 23, 25, 27) may be made of a wide band gap material having a larger band gap than a semiconductor material such as silicon (Si). However, the materials of the semiconductor material layers and the barrier layers constituting the switching device according to the exemplary embodiments are not limited thereto.

According to the exemplary embodiment illustrated in FIG. 16, there is an advantage in that higher current can be utilized by stacking multiple layers and utilizing them as channel materials. In addition, in the exemplary embodiment illustrated in FIG. 16, since the semiconductor material layers (22, 24, 26) are stacked alternately with the wide bandgap material layers (21, 23, 25, 27) to form quantum wells, electrons are confined in each semiconductor material layer (22, 24, 26), which is a narrow bandgap material, and it can act as an individual current channel. In this case, in order to move the current in the spin-polarized surface state formed in the multiple layers from the source electrode (10) to the drain electrode (30), the source electrode (10) and the drain electrode (30) can be in electrical contact with the channel material composed of multiple layers (i.e., the semiconductor material layers 22, 24, 26).

The switching device according to exemplary embodiments of the present disclosure can be utilized as a complementary logic device (CMOS). The spin-polarized surface state induced by the method according to exemplary embodiments is determined by the absolute value of the applied voltage, and the spin-polarized surface state can appear under both forward bias and reverse bias.

Therefore, in order for the switching device described above with reference to FIGS. 15 and 16 to operate as an inverter, which is the minimum unit constituting a complementary logic device, a first switching device (e.g., an N-type device) can be made to be in a linear spin-polarized surface state and a second switching device (e.g., a P-type device) can be made not to be in a linear spin-polarized surface state under the same gate voltage. The control of the spin-polarized surface state of each switching device can be achieved by controlling the electric field applied to each switching device, varying the doping type or concentration of the substrate constituting each switching device, or applying a body bias.

Although the present disclosure has been described above with reference to the exemplary embodiments illustrated in the drawings, they are merely exemplary and those skilled in the art will understand that various modifications and variations can be made to the exemplary embodiments. However, such modifications and variations should be considered as within the scope of the present disclosure. Therefore, the scope of the present disclosure should be determined by the technical idea of the appended claims.

What is claimed is:

1. A method for electrically controlling a spin-polarized surface state, the method comprising:
causing phase transition to a topological insulator by applying, to a semiconductor material, an electric field having a direction perpendicular to the surface of the semiconductor material,
wherein the electric field has a magnitude determined by a maximum value of a valence band and a minimum value of a conduction band of the semiconductor material.

2. The method for electrically controlling a spin-polarized surface state according to claim 1, wherein said causing the phase transition comprises forming a spin-polarized surface state by inducing interaction between wave functions existing on both surfaces of the semiconductor material through spin-orbit coupling.

3. The method for electrically controlling a spin-polarized surface state according to claim 1, wherein said causing the phase transition comprises applying an electric field such that a spin-polarized surface state electrically occurring in the semiconductor material is distributed linearly and a helical spin orientation is formed on the surface of the semiconductor material.

4. The method for electrically controlling a spin-polarized surface state according to claim 1, wherein said causing the phase transition comprises determining the magnitude of the electric field so that a product of an intensity of the electric field applied to the semiconductor material and a thickness of the semiconductor material is greater than or equal to a band gap of the semiconductor material.

5. An electrical switching method, comprising:
preparing a semiconductor material layer comprising a first contact point and a second contact point, which are electrically separated from each other, and a semiconductor material connecting the first contact point and the second contact point and having a predetermined thickness; and
in order to control the electrical connection between the first contact point and the second contact point, causing phase transition of the semiconductor material to a topological insulator by applying an electric field having a direction perpendicular to a surface of the semiconductor material to the semiconductor material layer,
wherein the electric field has a magnitude determined by a maximum value of a valence band and a minimum value of a conduction band of the semiconductor material.

6. The electrical switching method according to claim 5, wherein the semiconductor material layer is made of a direct bandgap semiconductor material having a spin-orbit coupling strength between graphene and a topological insulator and having symmetry between both surfaces.

7. The electrical switching method according to claim 6, wherein
the semiconductor material comprises silicon germanium (Si_{1-X}Ge_{X}) having a germanium (Ge) ratio of 85% or higher,
the predetermined thickness is 3 nm or smaller, and
said causing the phase transition comprises applying an electric field having a strength of 0.01×10¹² to 0.11×10¹² V/m to the semiconductor material layer.

8. The electrical switching method according to claim 6, wherein the semiconductor material comprises a group III-V semiconductor material comprising gallium (Ga) or indium (In) but excluding gallium phosphide (GaP).

9. The electrical switching method according to claim 6, wherein the semiconductor material comprises a group II-VI semiconductor material comprising cadmium (Cd) or zinc (Zn) but excluding cadmium oxide (CdO).

10. The electrical switching method according to claim 6, wherein the semiconductor material comprises an alloy based on a group IV element.

11. The electrical switching method according to claim 5, wherein said preparing the semiconductor material layer comprises stacking silicon germanium (Si₁₋ₓGe_{X}) having a germanium (Ge) ratio of 85% or higher in (111) direction.

12. A switching device comprising:
a first conductive layer;
a second conductive layer electrically separated from the first conductive layer;
a channel layer connecting the first conductive layer and the second conductive layer, made of a semiconductor material and having a predetermined thickness; and
a control unit configured to cause phase transition of the semiconductor material to a topological insulator by applying an electric field having a direction perpendicular to the surface of the semiconductor material to the channel layer to control electrical connection between the first contact point and the second contact point.

13. The switching device according to claim 12, wherein the channel layer is made of a direct bandgap semiconductor material having a spin-orbit coupling strength between graphene and a topological insulator and having symmetry between both end surfaces.

14. The switching device according to claim 13, wherein the control unit is further configured to selectively control the flow of current through the channel layer by applying an electric field to the channel layer so as to form a spin-polarized surface state by inducing interaction between wave functions existing on both surfaces of the semiconductor material through spin-orbit coupling.

15. The switching device according to claim 13, wherein the control unit is further configured to determine the magnitude of the electric field so that a product of an intensity of the electric field applied to the semiconductor material and a thickness of the semiconductor material is greater than or equal to the band gap of the semiconductor material.

16. The switching device according to claim 12, wherein
the semiconductor material comprises silicon germanium (Si_{1-X}Ge_{X}) having a germanium (Ge) ratio of 85% or higher, and
the predetermined thickness is 3 nm or smaller.

17. The switching device according to claim 16, wherein the semiconductor material is silicon germanium (Si₁₋ₓGe_{X}) stacked in (111) direction.

18. The switching device according to claim 12, wherein the channel layer comprises:
a plurality of semiconductor material layers made of the semiconductor material; and
a plurality of barrier layers, which are stacked alternately with the plurality of semiconductor material layers and are made of a material having a larger band gap than the semiconductor material layers.

19. The switching device according to claim 18, wherein
the semiconductor material is silicon germanium (Si_{1-X}Ge_{X}) having a germanium (Ge) ratio of 85% or higher, and
the barrier layer is made of silicon (Si).

20. A field-effect transistor comprising the switching device according to claim 12.
